(19) United States
(12) Patent Application Publication
(10) Pub. No.: US 2015/0187414 A1
(43) Pub. Date: Jul. 2, 2015

(54) DYNAMIC SENSE CIRCUITRY

(71) Applicant: HEWLETT-PACKARD DEVELOPMENT COMPANY, L.P., Houston, TX (US)

(72) Inventor: Frederick Perner, Santa Barbara, CA (US)

(21) Appl. No.: 14/415,268

(22) PCT Filed: Jul. 27, 2012
(86) PCT No.: PCT/US2012/048679

§ 371 Date: Jan. 16, 2015

(51) Int. Cl. G11C 13/00; H01L 45/00

(52) U.S. Cl. CPC G11C 13/004; H01L 45/12; G11C 2013/0042; G11C 2013/0054

(57) ABSTRACT

A dynamic sense circuit to determine memristor states within a memristor crossbar array that includes a differential comparator made up of a resistance capacitance (RC) network to capture a reference voltage and a differential pre-amp to operate in an open loop mode to dynamically compare the reference voltage to a sense voltage. An alternating current (AC) coupled amplifier receives the output of the comparator and outputs an amplified signal. A set-reset (SR) latch samples and holds the amplified signal as a digital value.

### BACKGROUND

Resistive arrays can be used to store digital data. Sense circuitry connected to the resistive arrays detects the state of resistive devices within the resistive array and sends these measurements to external circuitry for communication and processing.

### BRIEF DESCRIPTION OF THE DRAWINGS

The accompanying drawings illustrate various examples of the principles described herein and are a part of the specification. The illustrated examples are merely examples and do not limit the scope of the claims.

FIG. 1A is a block diagram of a portion of a resistive array connected to a high speed dynamic sense circuit, according to one example of principles described herein.

FIGS. 1B-1E describe generation of a reference voltage and a sense voltage from the resistive array, according to one example of principles described herein.

FIG. 2A is a circuit drawing of a dynamic differential comparator and its performance, according to one example of principles described herein.

FIG. 2B is a graph of inputs to a pre-amplifier in the dynamic differential comparator, according to one example of principles described herein.

FIG. 2C is an output signal from the pre-amplifier in the differential comparator, according to one example of principles described herein.

FIG. 3A is a more detailed circuit drawing of the dynamic differential comparator, according to one example of principles described herein.

FIG. 3B is a graph of control signals that configure the dynamic differential comparator, according to one example of principles described herein.

FIG. 4A is a circuit drawing of a fast AC coupled post amplifier, according to one example of principles described herein.

FIG. 4B is a graph of a control signal for the fast AC coupled post amplifier, according to one example of principles described herein.

FIG. 5A is a circuit drawing of a set-reset (SR) latch with a gate circuit for sampling the output of the AC amplifier during the sample window, according to one example of principles described herein.

FIG. 5B is a truth table for the set-reset (SR) latch shown in FIG. 5A, according to one example of principles described herein

FIG. 6A is a flowchart of a dynamic sense operation, according to one example of principles described herein.

FIG. 6B is a flowchart of a more detailed dynamic sense operation, according to one example of principles described herein.

Throughout the drawings, identical reference numbers designate similar, but not necessarily identical, elements.

### DETAILED DESCRIPTION

A variety of technologies and devices can be used to create resistive memory arrays. For example, programmable resistance random access devices (PRRAM), magnetroresistive random access memory (MRAM), metal oxide based memory cells and other memristive technologies are examples of resistive memory. For purposes of explanation, nonvolatile resistive memory technologies will all be described as “memristive” or as a “memristor(s).” The term “memristor” is a portmanteau of two terms: “memory” and “resistor.” Any resistive device that can be programmed to different resistive states and maintains the programmed resistance state for a designated period of time can be termed a memristor.

Memristors are time varying non-linear devices that have the potential to compete with available solid state memory in terms of density and power consumption. To form high density memory, memristors can be arranged in crossbar arrays with write and read circuitry arranged around the perimeter of the arrays. In one example, the crossbar array may include an upper layer of crossbars (row lines) and a lower layer of crossbars (column lines). The upper layer of crossbars is oriented so that they intersect the lower layer of crossbars. The memristors are formed at intersections of the upper and lower crossbars so that each memristor connects a different pair of upper and lower crossbars. In one example, the read and write circuitry address a targeted memristor by applying the appropriate voltage to a row crossbar and a column crossbar that are joined at their crossing point by the target memristor. A write voltage produces a change of state in the memristor. For example, the memristor may be programmed by applying a programming voltage to the appropriate column line and row line. The memristor will then be programmed to have either a high resistance state (“OFF” state) or a low resistance state (“ON” state). The OFF state may represent a binary “0” and the ON state may represent a binary “1”. These states remain substantially stable until another programming voltage is applied to the memristor. Thus, a large array of memristors can be programmed for nonvolatile storage of digital data.

The read circuitry is to detect the state of the memristors in the crossbar array without changing the state of the memristors. Thus, the energy applied during the read process is typically lower than the energy applied during the programming process. The challenge of reading the state of a specific memristor is complicated by a number of factors. Memristors in the same memristor array may have different electrical characteristics. Particularly as memristor sizes shrink to tens of nanometers, variations in the number of atoms contained in the switching layer and dopant atoms in the switching layer can produce substantial variations in the electrical performance of the memristors. Other possibilities include variations in the size and material composition of the memristors.

Other factors that vary between memristors include the location of the memristor within the array. For example, a memristor that is farther away from the read circuitry appears to have different electrical characteristics during reading than a memristor that is located next to the read circuitry.

These purely resistive crossbar arrays do not have integral isolation devices (such as diodes). This allows the structure of the cross point arrays to be relatively simple and compact but makes the state of the memory elements difficult to sense at high speeds. In order to overcome the challenges described above, sense circuitry may use multiple sample techniques and adaptive sense techniques that rely on analog feedback, which require long settling times for acquiring sense references and long delay times for stable, reliable sensing.

The principles described herein are directed systems and methods for reading the resistance states of memristors of a crossbar array. These principles describe dynamic sense circuitry that uses a two sample method to make accurate and extremely fast measurements of memristor states. The principles include auto-zeroing a pre-amplifier and a dynamic reference voltage and then developing a dynamic differential signal at an input of a pre-amplifier. In contrast to with the examples described above, the pre-amplifier operates in an open loop mode and consequently does not require feedback or incur long time delays for settling/stability. The output of the pre-amplifier is coupled to a high gain post-amplifier. The output analog signal of the post-amplifier is sampled by an output latch.

One example of a high speed dynamic sense circuit that implements these principles was simulated using SPICE® with 0.25 u CMOS transistor parameters. The high speed sense circuit demonstrated operation over a wide range of circuit parameters and exhibited read latency delays on the order of 200 nanoseconds or less. Alternative sensing circuits such as those described above, would have read latencies on the order of 1 microsecond to 10 microseconds. Thus, the principles described provide for 500% to 5000% decrease in the time to read resistive memory arrays.

In the following description, for purposes of explanation, numerous specific details are set forth in order to provide a thorough understanding of the present systems and methods. It will be apparent, however, to one skilled in the art that the present apparatus, systems and methods may be practiced without these specific details. Reference in the specification to “an example” or similar language means that a particular feature, structure, or characteristic described in connection with the example is included in at least that one example, but not necessarily in other examples.

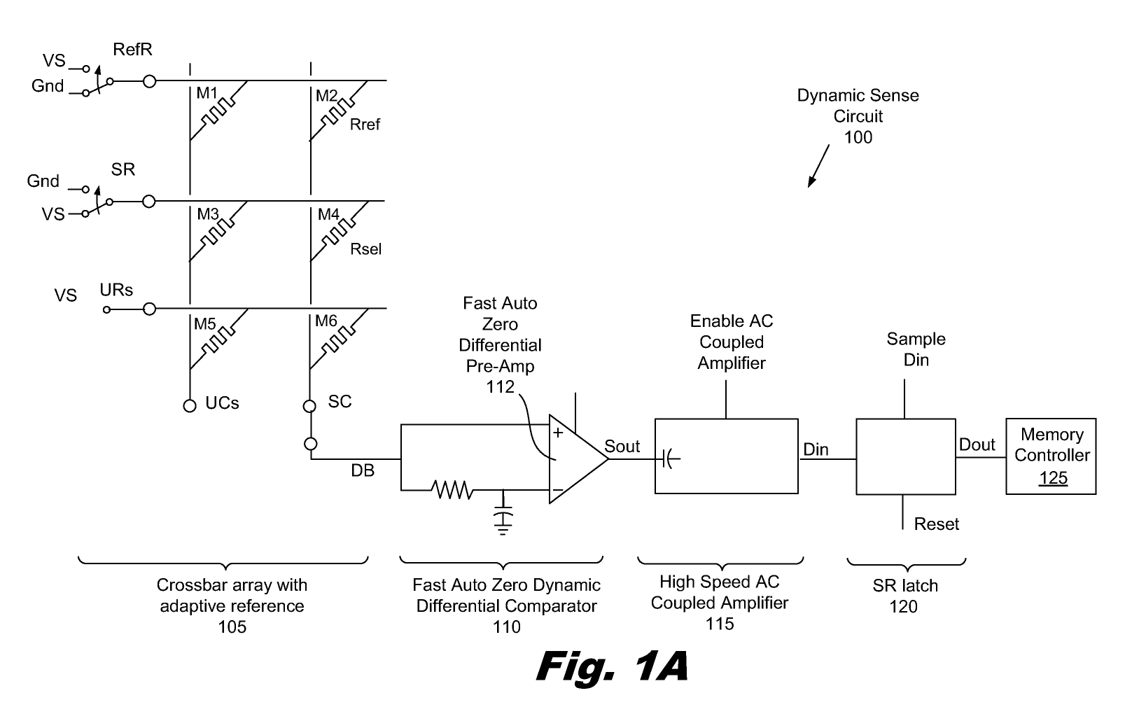

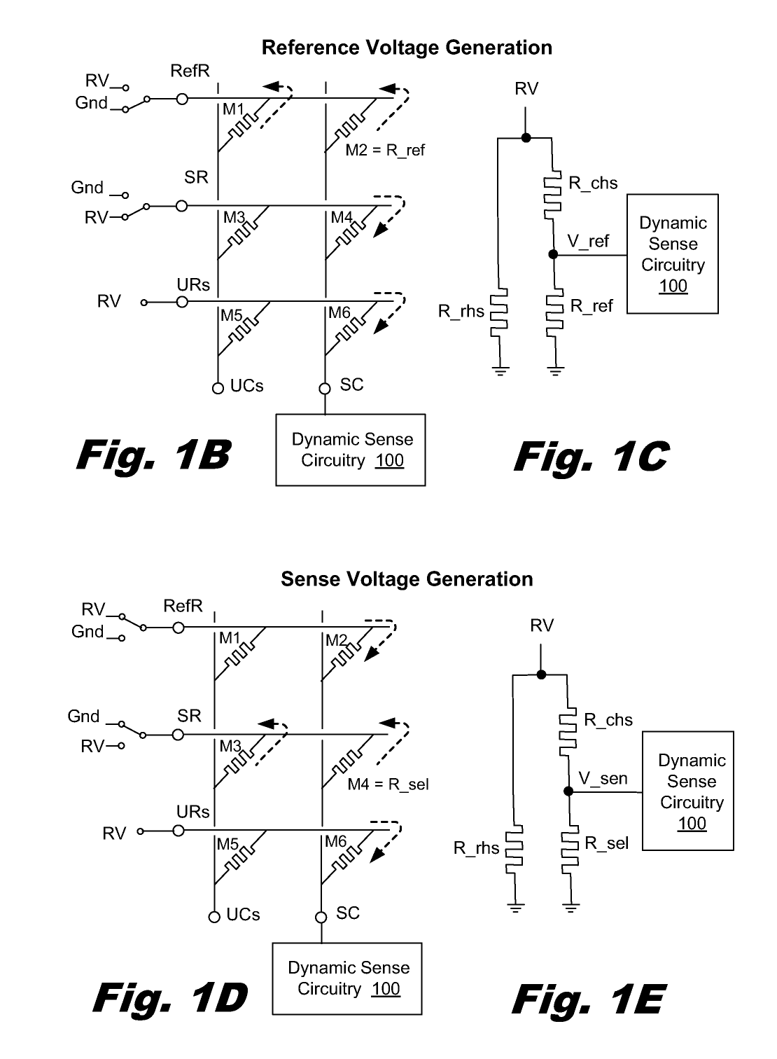

FIG. 1A is a block diagram of a portion of a resistive crossbar array (105) connected to a high speed dynamic sense circuit (100). The resistive crossbar array (105) has a number of horizontal row lines that cross over perpendicular column lines. However, the orientation angle between the row lines and column lines may vary. Each row line overlies all of the column lines and comes in close contact with each column line at the intersections. Resistive memory elements (e.g. M1-M6) form junctions between the row lines and column lines at each intersection. A data value can be stored in each memristor of a crossbar array using the high-resistance state of the memristor to represent a logic “0” bit value and the low-resistance state to represent a logic “1” bit value or vice versa, depending on the convention selected. The bit value stored at a crossbar junction can be “read” or “sensed” by determining the resistance state of the memristor.

To address a particular memristor device, the appropriate row and column lines are selected. Ideally, only the resistive device at the intersection of the selected row line and column line would influence the measurement. However, there are a number of other factors, including leakage paths through other memristors, which may obscure the resistance measurement. Although only three row lines and two column lines are illustrated, the array may include hundreds or thousands of row and column lines.

When a read or programming voltage is applied to a particular pair of row and column lines, a substantial portion of the applied current passes through the memristor at the intersection of the row line and column line. For example, in FIG. 1A, the selected row line may be the “SR” row line at the top of the figure. The selected column line may be the “SC” column. At the intersection between the SR row line and the SC column line is memristor M4 that has a resistance of Rsel. The resistance Rsel varies according to the programmed state of memristor M4. Ideally, all of the sense current applied would flow through memristor M4. This would allow the current to be measured and the state of memristor M4 to be determined. For example, if a large amount of current flowed through the memristor M4, it could be determined that memristor M4 is in a low resistance state. If a small amount of current flowed through memristor M4, it could be determined that memristor M4 was in a high resistance state. However, where the memristors in the crossbar array are purely resistive in nature, the surrounding memristor elements create “sneak paths” that allow for undesirable parasitic currents to flow between the SR row line and SC column line. For example, the current could flow through a memristor M6 to a row line labeled “URs” (Unselected Rows), through memristor M5 to the column line labeled “UCs” (Unselected Columns), and finally through the memristor M3 to the SR row line. Thus, the current passed from the selected column SC to the selected row SR without passing through the target memristor M4. In a large memristor array, the number of sneak paths is substantial and the current leakage can introduce a significant amount of noise into the measurement that obscures the state of the target memristor. Furthermore, this noise is dependent on the state of the unselected memristors. For example, if the memristors close to the target memristor are in a high resistance state, the leakage may be smaller than if the memristors are in a low resistance state.

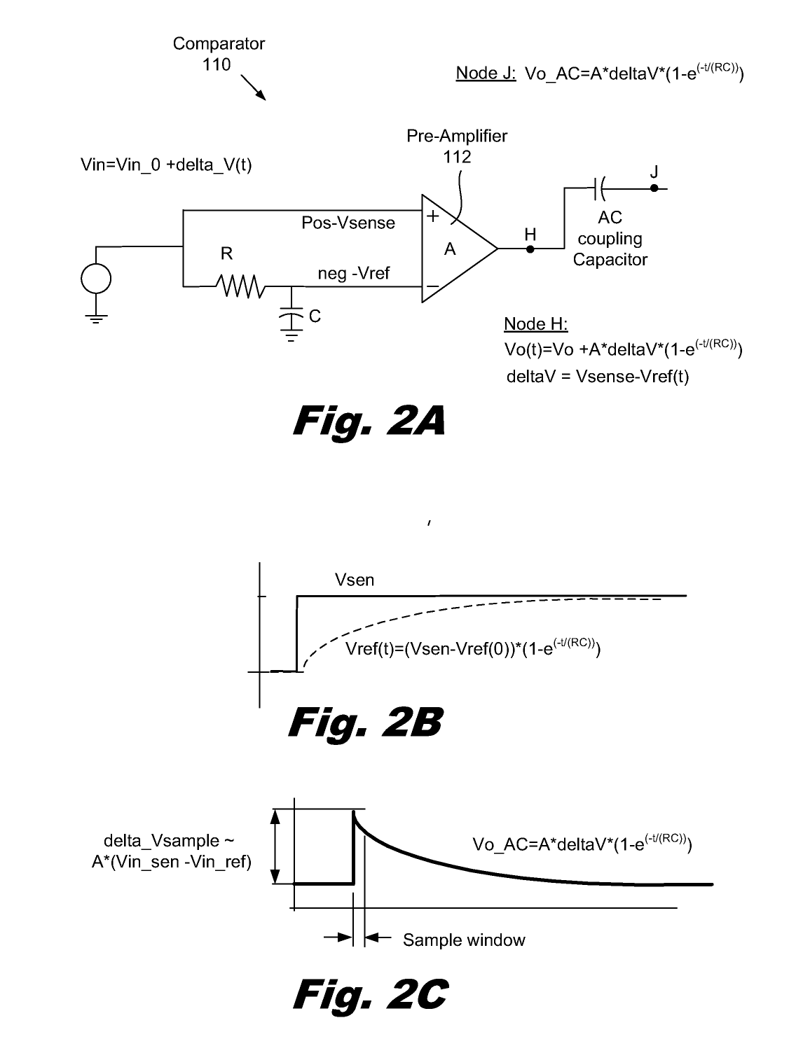

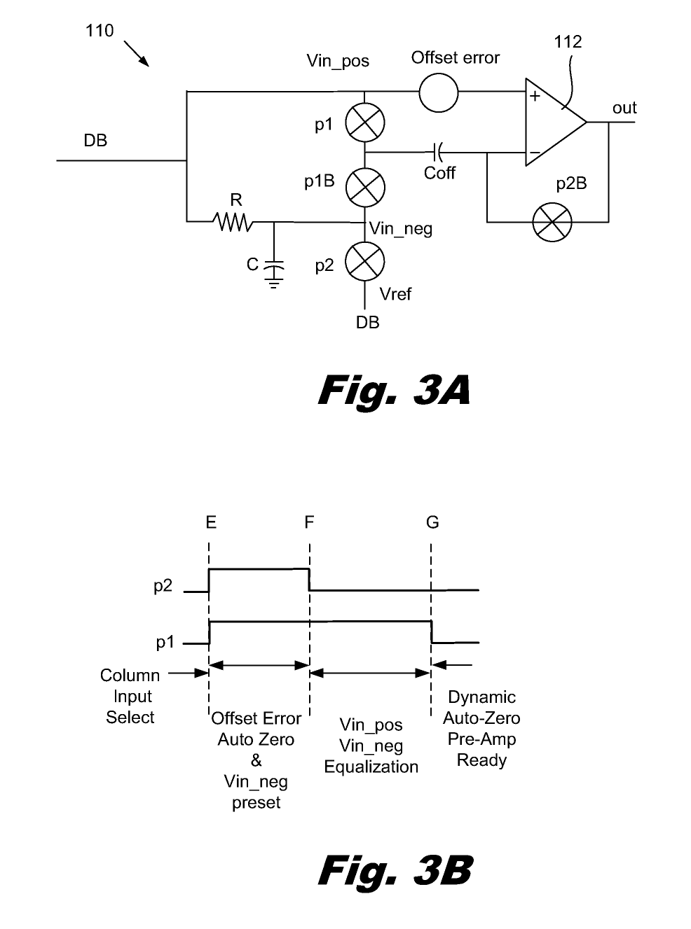

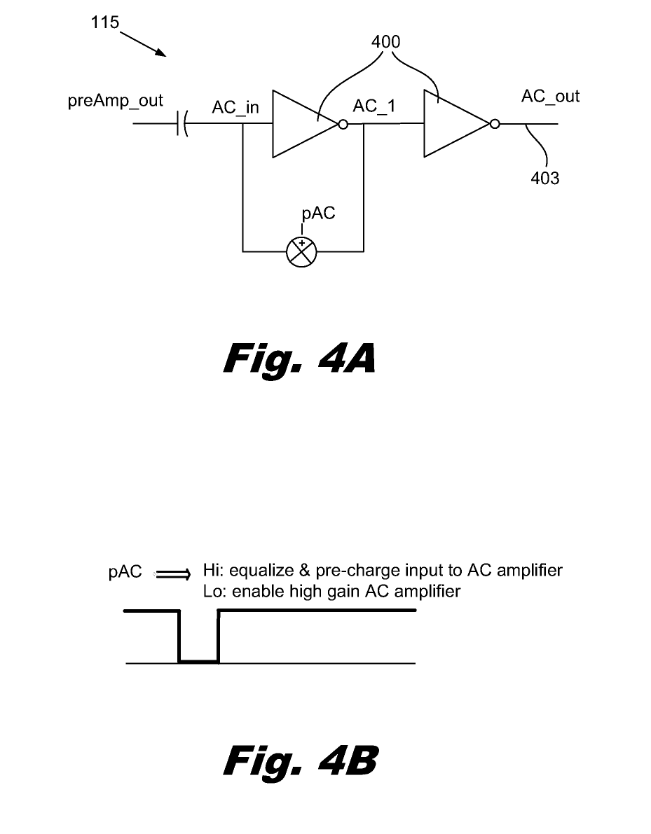

FIG. 1A also shows a dynamic sense circuit (100) that includes a fast auto zero dynamic amplifier (110), a high speed AC coupled amplifier (115) and a set-reset (SR) latch (120). The dynamic sense circuit is to make fast and accurate measurements of the state of memristors within the crossbar array. The fast auto-zero dynamic differential comparator (110) auto-zeros to reduce offset errors and stores a reference voltage representing a known resistance within the array. The fast auto-zero dynamic differential comparator (110) then compares the stored reference voltage to a sensed voltage using a differential pre-amp (112). The fast auto-zero dynamic differential comparator (110) is discussed in FIG. 2 and FIG. 3 in greater detail. The output (Sout) from the comparator (110) is received by the high speed AC coupled amplifier (115). The AC coupled amplifier (115) includes an AC coupling capacitor. The capacitor blocks DC voltages but allows AC voltages to pass into the amplifier (115). The amplifier (115) amplifies the AC output from the comparator (110) and outputs the result (Din) to an SR latch (120). The amplifier (115) is discussed in more detail in FIG. 4. The SR latch (120) includes a sample line, reset line and a Dout line. The SR latch (120) is used as sample-and-hold analog-to-digital converter. If the input (Din) of the SR latch (120) is above a predetermined threshold, the SR latch outputs a high digital signal on the output line Dout. If the input of the SR latch (120) is below a threshold, the SR latch outputs a low digital signal on the output line. A memory controller receives the digital signal from the SR latch for processing and communication.

There may be a number of additional components and variables that influence the measurement and operation of the system shown in FIG. 1. For example, the lines in the crossbar have a capacitance that may be a significant and limiting factor in making very fast measurements of memristors in the crossbar array.

The generation of the reference voltage and sense voltage will now be discussed with reference to FIGS. 1B-1E. FIGS. 1B-1E show that the selected column (SC) is connected to the input of the dynamic sense circuitry (100). Throughout the generation of the reference voltage and sense voltage, a read voltage RV is applied to all unselected rows (URs). As shown in FIG. 1B, to generate the reference voltage, the selected column SC is connected to the input (data bus line DB) of the comparator (110) and the reference row (RefR) is connected to ground (GND). Thus, all the row lines have RV applied except for the reference line RefR. Currents flowing from the charged row lines to the ground row line are shown as dashed arrows. The current flows through the half selected memristors (M4, M6) to the selected column line and through the reference memristor M2 to the grounded row line RefR. The resistance of the half selected (non target) memristors connected to the selected column line is designated as R_chs. The term “half selected” refers to memristors that are connected to one of the selected column or selected row, but not to both. In this example, the row RefR is selected and the column SC is selected. Memristors M1, M4, and M6 are half selected. Memristor M2 is selected. Memristors M3 and M5 are unselected.

Leakage currents travel through other paths within the memristor array and pass through half selected memristors connected to the grounded row line. In this example, memristor M1 represents these half selected memristors. The resistance of these leakage paths is designated as R_rhs.

FIG. 1C shows the electrical behavior of the crossbar array modeled as a voltage divider. The reading voltage RV is applied at the top of the voltage divider and the bottom of the voltage divider is connected to ground. The reference voltage V_ref is extracted at an intermediate point in the voltage divider by the dynamic sense circuitry (100). The voltage divider includes three resistances: R_chs which represents the resistance of half selected memristors connected to the selected column; R_rhs which represents the resistance of half selected memristors connected to the selected (grounded) row; and R_ref which represents a reference resistance (such a memristor M2 in a known resistance state).

The current induced by the applied read voltage flows through two paths: a first path through R_chs and R_ref and a second path through R_rhs. The reference voltage V_ref is extracted from the first path between R_chs and R_ref. The leakage currents flow through the second path. The actual resistance values depend on the programmed resistance states of the memristors that contribute to the resistance values.

FIG. 1D shows the generation and measurement of a sense voltage V_sen. The sense voltage is generated by switching reference line (RefR) to the read voltage RV and switching the selected row (SR) to ground GRD. This is illustrated by the positions of the switches on the left of the crossbar array. The read voltage RV remains connected to all of the unselected rows URs and is now applied to the reference row RefR. This results in the voltage divider shown in FIG. 1E. The resistance R_chs is substantially the same as when the reference voltage was generated. The only change in R_chs is the substitution of R_ref for R_sel. The leakage resistance value R_rhs can change somewhat due to the different memristors and paths that the leakage currents flow through.

After making the reference voltage and sense voltage measurements, the dynamic sense circuitry compares the measurements. This eliminates noise components that the two measurements have in common and emphasizes the difference (if any) in the resistance states of the reference memristor and selected memristor. For example, R_chs may be substantially the same in both measurements. A significant amount of the resistance R_rhs may remain the same. By differencing V_ref and V_sen, the comparator eliminates most of the noise in the measurements. Thus, the difference between the reference voltage and the sense voltage is primarily attributable to the difference in state between the reference memristor M2 and the selected memristor M4. The state of the reference memristor M2 is known. For example, the reference memristor M2 may be set to a high resistance. If the selected memristor M4 is also in a high resistance state, the difference between the reference voltage and the sense voltage will be minimal and will be below a sense threshold. However, if the selected memristor is in a low resistance state, the sense voltage will be greater than the reference voltage and will be above a sense threshold.

FIGS. 2A-2C show the operation of the fast auto zero dynamic differential comparator (110). The input to the dynamic differential comparator is shown in the left as Vin. Vin is either the reference voltage or the sense voltage depending on which step in the process is being performed. The input voltage Vin is defined as Vin_{—}0+delta_V(t). The Vin_{—}0 represents a base voltage (not time varying) to the circuit, and delta_V(t) represents the time varying component of the input voltage Vin. Vin_{—}0 is the reference voltage and delta_V(t) is the signal voltage which is the difference of the reference voltage and the sense voltage. If the resistance of M4 (the target memristor) is equal to M2 (the reference memristor), then deltaV(t) is approximately zero.

An RC circuit in the comparator (110) is used to sample Vref and hold Vref as a dynamic reference voltage which is later compared to the sense voltage Vsen by the differential pre-amplifier (112). For efficient CMOS layout concerns, the differential pre-amplifier may be a minimum size, five transistor, operational amplifier. If the differential pre-amplifier was an ideal amplifier, the output voltage would not change when an identical voltage is applied to both the positive and negative inputs. If there is a small difference between the positive and negative input voltages, as may be caused by offset error, the difference voltage will be multiplied by the gain of the amplifier and result in unpredictable positive or negative swings in the output voltage. This undesirable offset error is compensated for by an auto-zero technique.

The comparator (110) operates in two different modes or configurations: a setup mode and a sense mode. The setup mode begins with an ‘auto-zero’ operation that will cancel the effect of amplifier offset error. Additionally, a measurement of the reference voltage from the crossbar array is also made during the set-up mode. As discussed above with respect to FIGS. 1B and 1C, a column is selected and a reference row is selected so that a reference sense current will flow through the half selected elements connected to the selected column and unselected rows and through the reference device to create a reference sense voltage. The circuit connecting the half selected memory cells to the reference cell or the selected cell functions as a ‘voltage divider’ circuit. The reference voltage is applied directly to the positive input of the comparator and to the negative input of the comparator through a series resistor. The negative input will charge the capacitor ‘C’ to a voltage equal to the voltage applied to the positive input with an RC time delay. Hence, at the end of the setup mode, the positive and negative inputs to the differential comparator will be approximately equal.

A sense mode follows the setup mode where the reference device will be switched out (from ‘GND’ to ‘VR’, FIG. 1D) while simultaneously the selected device will be switched in (from ‘VR’ to ‘GND’, FIG. 1D). If the selected device is in a state with a resistance approximately equal to the reference device, the sense voltage will be approximately equal to the reference voltage stored in the setup mode and little or no change is expected at the output of the pre-amplifier. If, however, the resistance of the selected device is significantly different from the reference device, a large differential sense voltage (Vsen−Vref) coupled directly to the positive input of the comparator will cause a large change in the output of the pre-amplifier until the voltage on the negative input can RC charge to again be approximately equal to the sense voltage. Hence, a large input differential voltage will develop at the beginning of the sense mode and the differential voltage will decay to zero with an RC time constant. The pre-amplifier will produce the differenced voltage represented as Vo(t)=Vo+A*deltaV*(1−e^{(-t/(RC))}). Vo represents the non-time varying component and A*deltaV*(1−e^{(-t/(RC))}) represents the time varying differential voltage component multiplied by the amplification of the pre-amplifier. The term deltaV represents the difference between Vsen and Vref(t). The exponential components of the equation represent the resistance/capacitance (RC) time constant for the decay of Vref.

FIG. 2B shows the variation in the voltages applied to the positive and negative input terminals of the comparator during the sense mode. For purposes of description, Vsen is illustrated as a step function applied to the positive terminal of differential pre-amp. In practice, Vsen may exhibit capacitive, inductive, and resistive effects generated by the crossbar components. The signal on the negative terminal of the differential pre-amp is represented as a time varying signal shown as a dashed line and the equation Vref(t)=(Vsen−Vref0)*(1−exp(−t/(RC))). Vsen=Vref at the beginning of a sense mode with Vsen sharply rising and Vref following with an RC time constant defined by the components in the RC circuit. Vsen rises sharply in this example because the resistance of M4 is greater than the resistance of M2. The magnitude and direction of this step in the Vsen signal is dependent on the relative magnitudes of the resistance of M2 and M4. As discussed above, if M2 and M4 have the same memory state, then there will be minimal or no change in Vsen.

FIG. 2C shows the output of the differential comparator after it has been filtered by the AC coupling capacitor located in the high speed AC coupled amplifier ((115), FIG. 1A). Vo_AC (the AC component of the output of comparator) shows a sharp rise that corresponds to the step in Vsen. In this example, the resistance of the Rref memristor is low and the resistance of the Rsel memristor is high. Consequently, Vref, as captured in the capacitor C, is initially low. At the instant that the switch is made to input Vsen to the dynamic differential comparator, Vsen jumps to a high voltage level. Vref changes as a function of the capacitance of C and the resistance of R. Vref eventually increases to the value of Vsen as the Vsen voltage passes through the resistor R and fills capacitor C. The description given above is only one example of the behavior of an illustrative circuit when the resistance of M4 is significantly higher than the resistance of M2. As discussed above, if the resistance states of M4 and M2 are similar, the Vo_AC will remain relatively constant when Vsen is applied.

A sample window is opened to sense the magnitude of the Vo_AC step to be conveyed to the output data latch through the AC coupled post-amplifier. As discussed above, the differential comparator differences the Vref input on the negative line and Vsen input on the positive line. The AC coupling capacitor blocks the DC component (Vo) of the resulting voltage signal. The amplitude of the output of the differential comparator peaks just after Vsen is introduced and before the reference voltage has decayed. A sample window is opened to sense the magnitude of the Vo_AC step to be conveyed to the output data latch through the AC coupled post-amplifier. The sample window is selected right after Vsen is switched into the circuit. This ensures that the maximum difference between the Vref and Vsen is measured. This is captured as delta_Vsample˜A*(Vin_sen−Vin_ref), where ‘A’ is an amplification factor that is a characteristic of the pre-amplifier.

FIGS. 3A and 3B are more detailed circuit drawings of the Auto Zero, Dynamic Differential Comparator. The differential comparator can be configured in two different operational modes: a set up mode and a sense mode. The configuration and operation of the differential comparator in each of these modes will now be described.

FIG. 3A shows more details about the components and functions of the dynamic differential comparator. As discussed above, the dynamic differential comparator includes a resistor (R) and a capacitor (C). These components are used to create the dynamic reference voltage. The resistor is interposed between a data bus (DB) or input line. One side of the capacitor is grounded. The comparator includes four switches labeled p1, p1B, p2, and p2B. The switches p1 and p1B are controlled by a first control signal p1. Switches p2 and p2B are controlled by a second control signal p2. The comparator also includes an offset capacitor (Coff).

In the setup mode, the auto-zero operation, the capture of the Vref voltage in the RC circuit, and equalization of the Vin_pos and Vin_neg nodes occur. Some amount of offset error in the pre-amplifier can be expected. The ‘auto-zero’ portion of the circuit generates an input offset voltage to neutralize offset error inherent in the differential pre-amplifier. The basic idea of offset cancellation is to sample the offset of the pre-amplifier during one clock phase and subtract it from the signal during the other clock phase. The setup mode enables the sampling of the offset by forming a unity gain closed feedback loop that feeds the output (Voffset) of the pre-amplifier back into a capacitor Coff connected to the negative input of the pre-amplifier. In this example, this is accomplished by the control signal p2 being high to close switch P2B. The feedback through switch p2B charges capacitor Coff. The capacitor Coff represents output load of the gain state during phase 1. Later in the sense phase, switch p2B is open so that the gain stage is in the open loop configuration and an offset free comparison is performed.

To capture the Vref voltage in the RC circuit, switch p2 is closed to quickly charge capacitor C to approximately Vref and is opened to allow Vref current to flow into the RC circuit and complete the charging of capacitor C. This operation occurs simultaneously with the auto-zero operation. After the auto-zero operation and charging of the capacitor C with Vref is complete, switches p1 and p1B remain closed to allow the equalization of the Vin_pos and Vin_neg nodes to Vref. This provides a fast, initial charge of Vin_neg node to Vref. The final charge of Vin_neg to Vref is through the RC network. The use of the RC network and the fast charge is a means to avoid the effect of ‘clock feedthrough.’

When the offset capacitor Coff has captured the offset error, the capacitor C has captured the reference voltage Vref and the two nodes (Vin_pos, Vin_neg) have equalized, the comparator is ready to switch into the sensing mode.

FIG. 3B shows the timing of the control signals p1 and p2 during the set-up mode. On the left of the graph, both p1 and p2 are low. At time E, both p1 and p2 go high. This closes all of the switches in the comparator. The offset error of the comparator is fed back through the feedback loop (p2B) and into the capacitor Coff. This auto zeros the pre-amplifier to compensate for any undesired offset. As discussed above, Vref partially charges capacitor C by passing through switch p2. This captures the reference voltage for later comparison.

At time F, p2 goes low but p1 remains high. This allows nodes Vin_pos and Vin_neg to equalize. At time G, p1 goes low and all switches in the comparator are open. The dynamic auto-zero pre-amp is ready for the sense mode.

In the sense mode, switch p1B is closed but all other switches remain open. This allows the captured reference voltage Vref to pass through p1B and the offset error correction capacitor Coff to the negative input of the pre-amplifier. Vsen is applied on the data bus line which is directly connected to the positive input of the pre-amplifier. As discussed above, Vref decays according to an RC time constant to eventually match Vsen. However, the initial value of Vref sensed at the negative terminal of the pre-amplifier is approximately the true value of Vref. The pre-amplifier compares this Vref value to Vsen before significant change in the value of Vref occurs. The pre-amplifier outputs this difference as discussed with reference to FIG. 2C.

FIG. 4A is an illustration of a fast, high gain AC coupled, post-amplifier (115). The amplifier (115) receives an input signal on the preAmp_out line, from the Auto-Zero Differential Pre-Amp discussed previously and seen in FIG. 3A. A set of series inverters (400) function as a fast post-amplifier to generate a large swing output voltage on the AC_out line. An equalization switch, labeled pAC, is wrapped around the left inverter (400) to pre-charge the input to a mid-VDD value, just prior to sampling the output of the pre-amplifier seen in FIG. 3A.

FIG. 4B illustrates a timing and state graph of the equalization switch pAC, shown in FIG. 4A. As can be seen, the switch idles in the “Hi” state where it equalizes and pre-charges the input, AC_in, to the amplifier. When sampling of the Auto-Zero Differential Pre-Amp (112, FIG. 3A) occurs, the equalization switch, pAC, transitions to “Lo”, enabling the high gain AC amplifier (115) to quickly amplify the signal on the input line, AC_in. After the signal on the input line is amplified, it is available on the output line, AC_out (403), and is ready for sampling by the SR latch (120) mentioned in FIG. 1A.

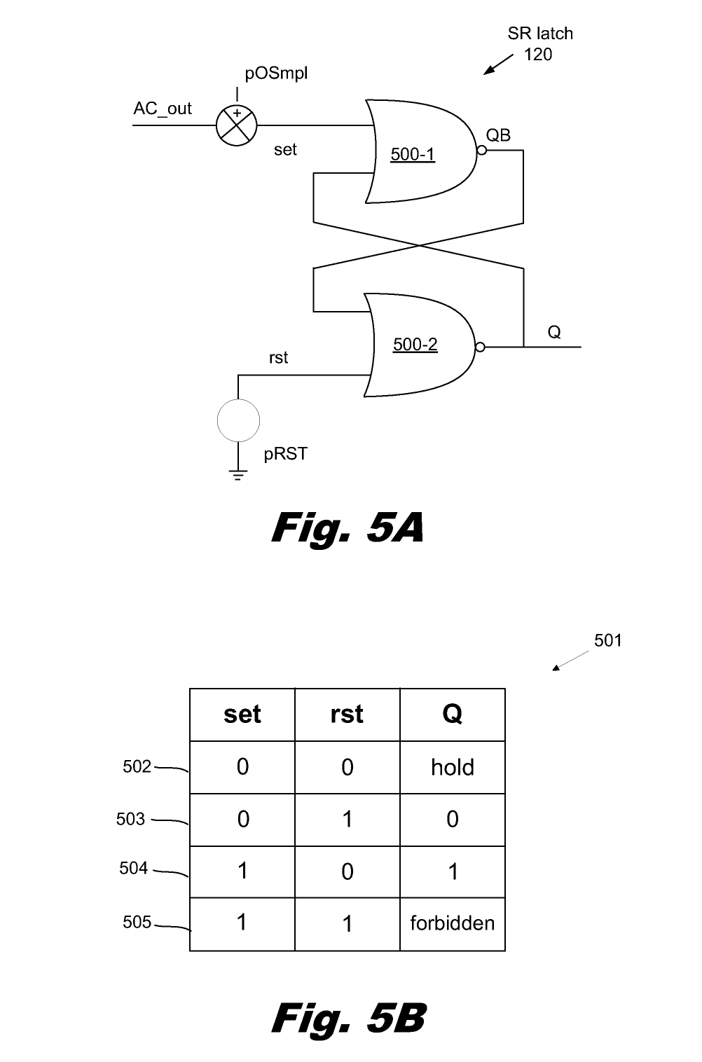

Illustrated in FIG. 5A is a set-reset (SR) latch (120). In the illustrated example, the SR latch is comprised of two NOR gates (500) and interconnecting wires. Although this particular SR latch (500) is designed with two NOR gates (500), it should be noted that other logical gates can be used to produce similar functionality. As the name of the latch indicates (set-reset) it has the ability to set and reset its output on Q. This is achieved by way of two inputs, namely, “set” and “rst”. The possible outputs on Q and QB (“Q not,”) are high and low or respectively 1 and 0.

The truth table (501) in FIG. 5B shows all the possible combinations of inputs on the set and rst lines, and the respective results produced on the output Q. Although QB is considered an output, it is not one that is used in this particular example. Note that the outputs, Q and QB need to be opposite. For example, if Q is a logical 1, then QB must be a logical 0. As can been seen in the table (501), when reset and set are both a logical 1, the output on Q is considered forbidden. This result is considered forbidden because both Q and QB would be a logical 0, breaking the rule that the outputs, Q and QB, must be opposite.

As seen in the table (501), in the first row (502), the SR latch (120) will hold the current value on the output Q, when both set and rst are a logical 0. When set receives a logical 1, and rst receives a logical 0, shown in the third row (504), the output Q will be set to a logical 1. The final valid combo, seen in row two (503), is set receiving a logical 0 and rst receiving a logical 1, which results in the output Q being set to a logical 0.

The digital output on Q of the SR latch (120) is held with this valid data, generally for the duration of the READ cycle, until the latch is reset, by way of the rst input. In this particular example, the SR latch is considered gated. The pOSmpl gate is placed on the set input line to either deny or allow an input to pass. The gate is closed, blocking all incoming signals, until the proper sampling window arrives. During the sampling window, the pOSmpl gate is disabled, allowing any signal to pass, and therefore perform their perspective action. After the output has been correctly loaded, it can be communicated to the memory controller (125).

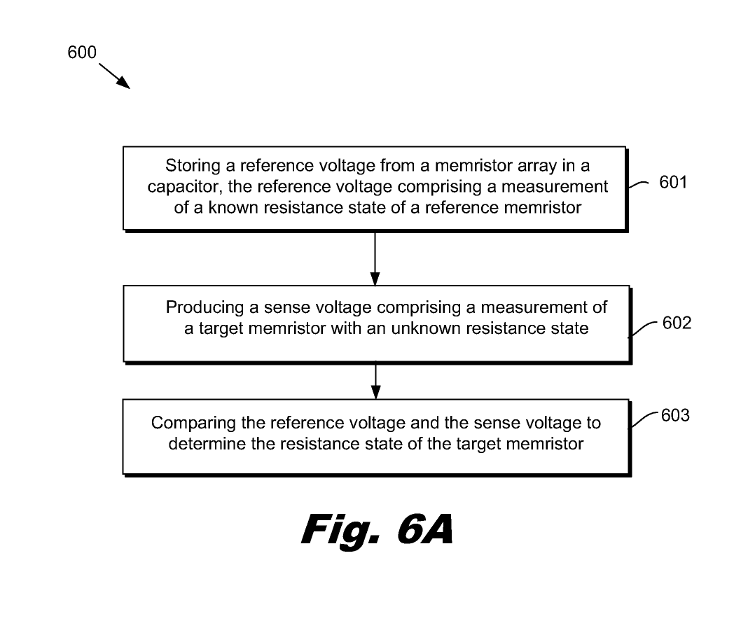

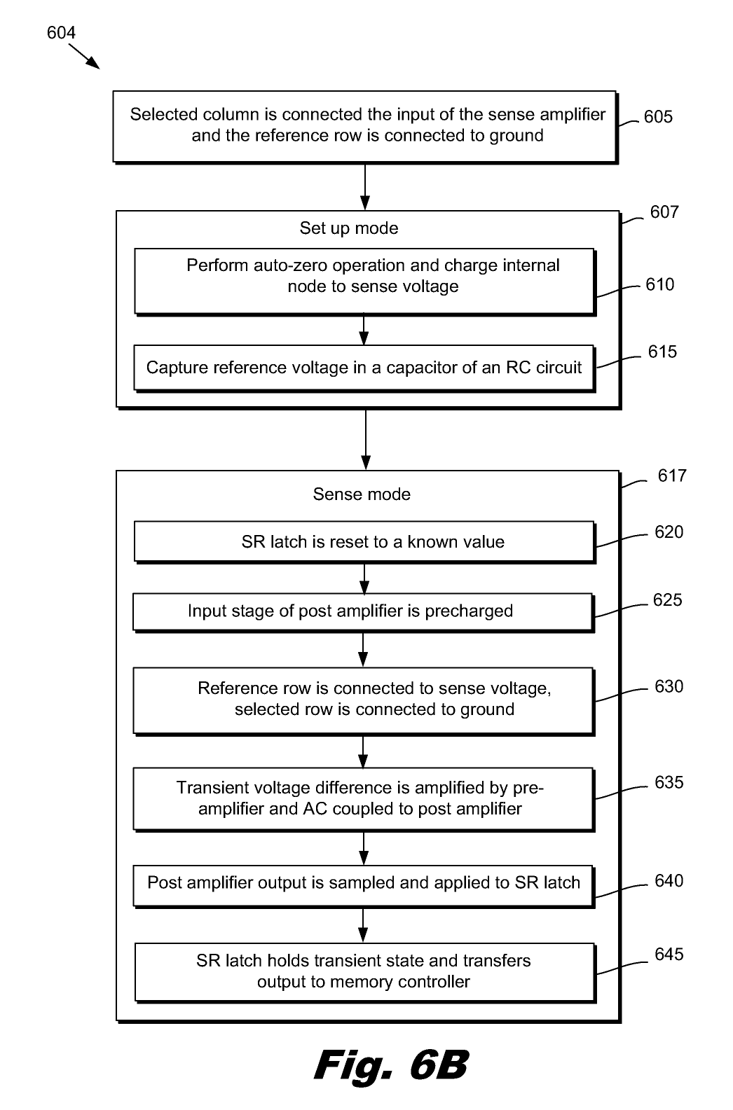

FIG. 6A is a flow chart of a general method (600) for high speed state detection in a memristive array that applies principles described herein. The method includes storing a reference voltage from a memristor array in a capacitor. The reference voltage includes a measurement of a known resistance state of a reference memristor (block 601). A sense voltage is produced that is a measurement of a target (selected) memristor with an unknown resistance state (block 602). The reference voltage and the sense voltage are compared to determine the resistance state of the target memristor (block 603).

FIG. 6B is a flowchart of a more detailed method (604) for the operation of the dynamic sense circuitry. Before the sense operation begins, the selected column SC is connected to the input of the sense amplifier (Vin_sense) and the reference row is connected to GND (block 605). This sets up the sense reference voltage as a function of the reference device and the data dependent, half selected devices connected to the selected column.

The set up operation (block 607) begins by performing the auto-zero operation (block 610) and capturing the sense reference voltage (block 615). The auto-zero operation is executed on the pre-amplifier while an internal node (Vin_neg) is pre-charged to the sense voltage (Vin_sense). After the auto-zero/pre-charge operation, the node Vin_neg is then allowed to adjust the input sense reference voltage to further approach (Vin_sense) with an RC time constant (block 615).

The sense mode operation (block 617) follows the set up operation. In one implementation, the sense mode operation includes the following sequence. The SR latch is reset so that V_data_out (Q) is reset to a known value (block 620). The input stage of the post amplifier is pre-charged to a high gain bias point (equalize) (block 625). The reference row is connected to the READ sense voltage (VS) and the selected row is simultaneously connected to GND (block 630). The transient initiated by the switch of the reference row and selected row causes a step in Vin_sense. The step is also applied to Vin_ref through the RC circuit with a delayed RC response. For a reasonable time window, the transient will cause a large difference voltage to be applied to the comparator (Vin_sense(t)−Vin_ref(0)).

The transient difference is amplified by the pre-amplifier and AC coupled to the high gain post amplifier (block 635). The large transient signal out of the post amplifier is sampled and applied to the SR latch (block 640). The last step in the sense operation is to hold the transient state out of the post amplifier in a set-reset latch which is coupled to a memory controller circuit (block 645).

In conclusion, the dynamic sense circuitry includes a “Fast Auto Zero, Dynamic Differential Comparator” pre-amplifier followed by a high speed, AC coupled post amplifier block and a set-reset data latch. The high speed pre-amplifier dynamically creates a reference voltage using a reference memory cell in the selected column in a cross point array of resistive memory cells and to amplify the dynamic difference between the sense voltage and the reference voltage using a high gain, high speed, differential amplifier. The output of the differential amplifier is then AC coupled to the high gain, high speed post amplifier and the set-reset latch.

The reference voltage is setup and stored on the storage capacitor coupled to the sense signal through a series resistor. In the sense mode, an unknown memory cell is connected to the selected column while, simultaneously, the reference cell is disconnected, causing the sense voltage to be applied to one node of a differential comparator and a delayed sense voltage to be applied to the second node of the differential comparator through a series resistor connected to the storage capacitor that is initially charged to the reference voltage. The difference between the sense voltage and the RC delayed sense voltage on the storage capacitor is amplified through an AC coupled amplifier and the result is stored in a clocked latch circuit to complete the sense amplifier operation.

The principles described herein allow extremely fast read time of state within resistive arrays. The read latency issue is solved in this design in at least two ways. First, the pre-amplifier is operated in an open-loop mode, eliminating the need to slow the amplifier down for closed loop stability considerations and eliminating the need to add time delay while a closed loop feedback system settles to an acceptable operating point.

Second, an RC network is introduced as a dynamic sample-and-hold circuit in place of conventional switched, sample-and-hold circuits. An RC network will hold a reference voltage long enough to complete a comparison operation without the need for sample-and-hold circuitry and the need for inserting sample-and-hold clock delays. Eliminating sample-and-hold clock delays and feedback amplifier settling time delays will significantly improve the read latency performance for sensing resistive cross point memory arrays. For example, a 50× improvement in read latency is demonstrated for a set of array parameters that represent a 1K by 1K array of memristor memory elements with a low resistance state of 10 meg-ohms, a resistance ratio of 10 and a memristor READ nonlinearity (Kr) of 10.

The principles described above allow for the simplification of the pre-amplifier design by eliminating the need for a feedback control network. By operating without a feedback network, i.e., in an open-loop mode, eliminated closed loop stability issues and delays associated with intentionally slowing the amplifier down and requiring extra settling time. Another advantage of the principles described is the use of a simple RC network to capture the sense-reference voltage instead of a sample-and-hold network. The simplification in the pre-amplifier and reference voltage circuit allows for shorter read latency delay times and offers significant simplifications in the physical circuit design. This provides for significantly faster read times and smaller footprints for reading circuitry.

The preceding description has been presented only to illustrate and describe examples of the principles described. This description is not intended to be exhaustive or to limit these principles to any precise form disclosed. Many modifications and variations are possible in light of the above teaching.

What is claimed is:

1. A dynamic sense circuit to determine memristor states within a memristor crossbar array comprising:
a differential comparator comprising:
a resistance capacitance (RC) network to capture a reference voltage;
a differential pre-amp to operate in an open loop mode to dynamically compare the reference voltage to a sense voltage;
an alternating current (AC) coupled amplifier to receive an output of the comparator and output an amplified signal; and
a set-reset (SR) latch to sample and hold the amplified signal as a digital value.

2. The circuit of claim 1, in which the comparator comprises a set up mode, the set-up mode comprising a feedback loop to auto-zero the differential pre-amp and a switch to direct the reference voltage to a capacitor in the RC network.

3. The circuit of claim 2, in which the comparator comprises a sense mode, the sense mode comprising a switch to open a feedback loop of the auto-zero differential pre-amp and a switch to direct the reference voltage captured in the capacitor to the differential pre-amp.

4. The circuit of claim 1, in which the read time of the dynamic sense circuit to determine a memristor state of a memristor within the memristor crossbar array is less than 200 nanoseconds.

5. The circuit of claim 1, in which a resistor in the RC network is interposed between a data bus DB line connected to the memristor array and an input line of the differential pre-amp.

6. The circuit of claim 5, in which a capacitor is connected between the RC network and the input line of the differential pre-amp.

7. A system comprising:
a memristor crossbar array with an adaptive reference, the memristor crossbar array comprising a reference memristor with a known resistive state and a target memristor with an unknown resistive state;
a reference voltage produced by a current passing through the memristor crossbar array, at least a portion of the current passing through the reference memristor;
a sense voltage produced by a current passing through the memristor crossbar array, at least a portion of the current passing through the target memristor;
a dynamic sense circuitry to connect to the memristor crossbar array, the dynamic sense circuitry comprising:
an auto zero comparator comprising:
an RC circuit to capture the reference voltage;
an auto-zero differential pre-amp to receive the reference voltage from the RC circuit and the sense voltage; and to difference the reference voltage and the sense voltage to produce a differenced output;
an AC coupled amplifier to receive and amplify the differenced output; and
an SR latch to receive the amplified differenced output and to produce a digital voltage signal corresponding to the differenced output; and
a memory controller to receive the digital output signal.

8. The system of claim 7, in which the adaptive reference comprises a first state and a second state, wherein the first state comprises a first voltage divider comprising the reference memristor; and the second state comprises a second voltage divider comprising the target memristor.

9. A method for high speed state detection in a memristive array comprises:
storing a reference voltage from a memristor array in a capacitor, the reference voltage comprising a measurement of a known resistance state of a reference memristor;
producing a sense voltage comprising a measurement of a target memristor with an unknown resistance state; and
comparing the reference voltage and the sense voltage to determine the resistance state of the target memristor.

10. The method of claim 9, in which the reference voltage is generated by:
applying a reading voltage to all rows in the memristor array but the row containing the reference memristor; and
grounding the row containing the reference memristor.

11. The method of claim 9, in which producing the sense voltage comprises
applying a reading voltage to all rows in the memristor array but the row containing the target memristor; and
grounding the row containing the target memristor.

12. The method of claim 9, in which comparing the reference voltage to the sense voltage comprises simultaneously:
connecting the sense voltage to a first line of a differential pre-amplifier; and
connecting the reference voltage from the capacitor to a second line of the differential pre-amplifier.

13. The method of claim 12, further comprising:
sampling the output of the dynamic differential comparator to produce a difference voltage; and
amplifying the difference voltage.

14. The method of claim 13, further comprising capturing the amplified difference voltage in a latch as a digital output signal.

15. The method of claim 9, further comprising auto-zeroing the dynamic comparator at the same time the reference voltage from the memristor array is stored in the capacitor.
